(19) United States
(12) Patent Application Publication
(10) Pub. No.: US 2005/0142290 A1
(43) Pub. Date: Jun. 30, 2005

(54) Substrate support adapter system

(76) Inventors: Stefan Kempf, Alzenau (DE); Thomas Merz, Aschaffenburg (DE); Steffen Runkel, Grundau-Lieblos (DE)

Correspondence Address: George W. Rauchfuss, Jr.;Ohlandt, Greeley, Ruggiero & Perle, L.L.P., Tenth Floor, One Landmark Square, Stamford, CT, 06901-2682, US

(21) Appl. No.: 10/998,206

(22) Filed: Nov. 26, 2004

(30) Foreign Application Priority Data
Nov. 28, 2003 (DE) 103 55 679.6

(51) Int. Cl. C23C 16/00; H05K 3/00

(52) U.S. Cl. 427/248.1; 118/715; 118/728; 427/255.5

(57) ABSTRACT

The present invention provides a substrate support adapter system, wherein the substrate support comprises an internal space in which at least one substrate can be arranged as well as an annular outer wall extending vertically with respect to the center plane of the substrate support and limiting the internal space towards the outside. On the outer circumference of the wall of the substrate support, a circumference convex projection, whose vertex is intersected by the center plane, as well as two circumferential concave grooves extending symmetrically with respect to the center plane are arranged as adapters, which are intended for engaging with a holding and/or gripping means for the substrate support. The present invention is advantageous in that a uniform device for manipulating substrates having different shapes and sizes in one system is provided. In particular, the substrate support which is open on both sides vertically with respect to the center plane can be used for treating substrates on one sides or on two sides.

The present invention relates to a substrate support adapter system, wherein the substrate support or carrier comprises adapters in the form of means for holding and/or gripping the substrate support. The substrate support is configured as a ring which is open in the axial direction, supports at least one substrate and is suitable for treating the substrate on one side or on both sides.

The prior art is faced with the problem to handle or treat substrates having different shapes and sizes in one system. In order to overcome this problem, different substrate supports are used which are differently adapted to the holding systems for the substrate supports.

It is the object of the present invention to provide a substrate support adapter system which allows substrates having different shapes and sizes to be held and transported in or through a system and which has a variety of applications. This object is achieved with the features of the claims.

In achieving the object, the invention starts out from the following basic ideas.

The substrate support is configured as a ring enclosing an internal space and comprising on its outer circumference means for engaging with a holding and/or gripping device. The internal space can be freely defined and can accommodate holding devices for different substrates which can be treated on one side or on both sides because the internal space is closed only by the annular or ring-shaped outer wall. The outer wall is defined geometrically and consists of two circumferential concave grooves being arranged symmetrical with respect to the center plane of the ring as well as of a circumferential convex projection whose vertex intersects the center plane of the substrate support ring. The substrate support is held by rollers which either engage with the grooves or are spring-mounted on the projection in combination with a stop. Moreover, the substrate support can be held on the projection by the surfaces of a V-shaped annular groove.

The invention provides a uniform connecting point (adapter) to different substrates, which can take over a plurality of functions. In coating processes, the substrate ring protects other machine parts from being coated unintentionally (masking, shielding). In sputter coating processes, the wall of the substrate ring can serve as an anode surface for the process. The wall of the substrate ring can accommodate additional components (e.g., transponders for identifying the support ring or the like. In the internal space of the substrate support ring, the substrate is well protected from damage. In addition to being used in coating processes, the substrate support can also be used in previous and subsequent processes, e.g., for cleaning. In particular, the invention can be used for the treatment of, e.g., CDs, DVDs, optical lenses or lenses of spectacles.

In the following, the invention will be described in more detail on the basis of the drawings in which

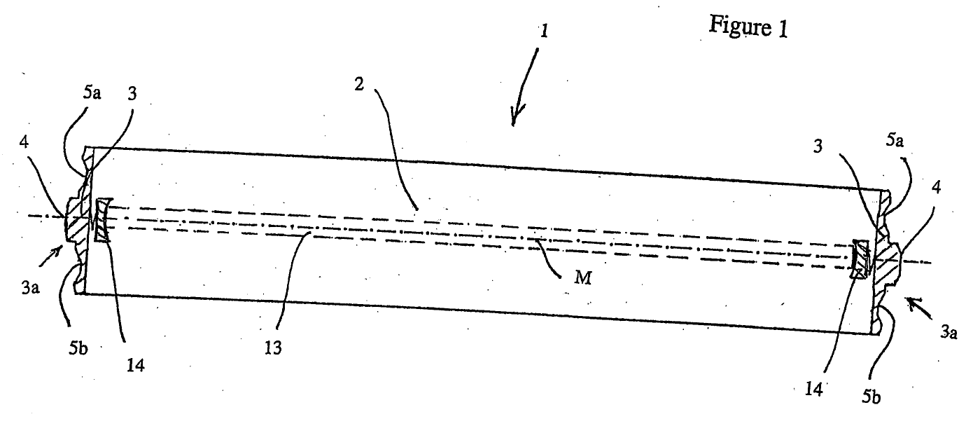

FIG. 1 is a cross-sectional view of the substrate support according to the present invention,

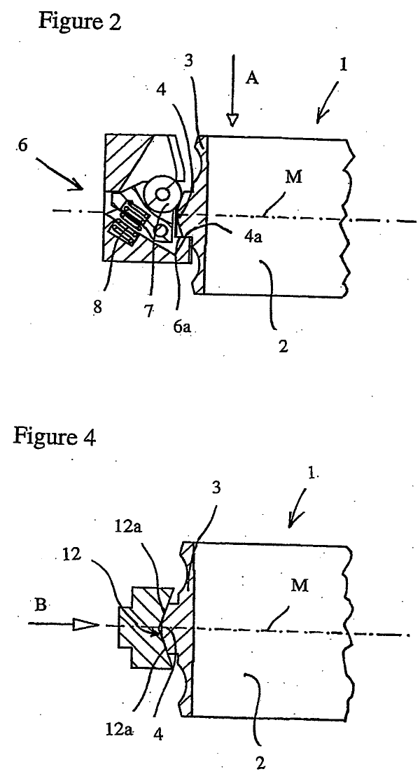

FIG. 2 is a cross-sectional view of the outer wall of the substrate support according to the present invention being engaged with a holding device,

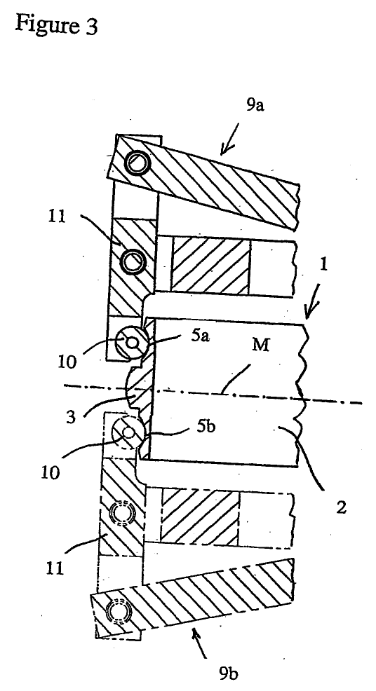

FIG. 3 is a cross-sectional view of the outer wall of the substrate support according to the present invention being engaged with two gripping devices, and

FIG. 4 is a cross-sectional view of the wall of the substrate support according to the present invention being engaged with a further gripping device.

FIG. 1 shows a cross-sectional view of the substrate support 1 according to the present invention. The substrate support comprises an internal space 2 for receiving at least one substrate 13. The internal space is surrounded by an annular wall 3 extending vertically with respect to the center plane M of the substrate support. The internal space 2, which is freely definable, can accommodate means 14 for holding one or more substrates, which are, e.g., spring-mounted on the wall 3, wherein the substrate 13 (dashed) is preferably arranged symmetrical with respect to the plane M. The holding means 14 are shown only schematically because their shapes have to be adapted to the substrate used.

Since the internal space 2 is open on both sides vertically with respect to the center plane M, both one-sided and two-sided treatment processes can be carried out. On the outer circumference 3a of the wall 3, there is a circumferential convex projection 4 which is symmetrical with respect to the center plane M and whose vertex intersects the center plane M. Moreover, two circumferential concave grooves 5a and 5b are arranged on the one side and the other side of the center plane, i.e. in the drawing above and below the center plane, and symmetrical thereto. The projection 4 and the grooves 5a and 5b are intended for engaging at least one holding and/or gripping device which either holds the substrate support passively or grips it actively in order to transport the substrate support ring or transfer it to different holding and gripping devices.

FIG. 2 shows a substrate support 1 being held in a passive holding device (spring-loaded tension roller) 6; a spring 8 presses a roller 7 against the projection 4 (in the drawing) above the center plane M, and a stopping surface 6a of the holding device 6 serves as the stop on which the projection 4 rests with its surface 4a below the center plane M. The substrate support 1 is introduced by means of pressure into said passive holding device 6 rolling or sliding manner up to the stop on the surface 6a. The straight stopping surface 4a of the projection 4 guarantees a defined height position of the substrate support. The spring-loaded roller holds the substrate support with a defined force. Additionally, the substrate support can be centered if at least three or more holding devices 6 with the spring-loaded tension rollers are arranged on the circumference of the ring. Apart from the holding device 6, also other positive-locking holding systems, which can be engaged with the structured surface of the wall 3 of the substrate support, can be used.

FIG. 3 shows a cross-sectional view of the outer wall 3 of the substrate support adapter system 1 being engaged with first and second gripping devices comprising gripping means 9a and 9b, respectively. The ring means each comprise a gripping finger 11; a roller 10 is arranged at the end of the gripping finger 11; the rollers 10 are engaged with grooves 5a and 5b of the substrate support 1, respectively. The radius of the groove 5a, 5b is slightly larger than the radius of the roller 10 so that the substrate support 1 is automatically aligned (or self-aligned) vertically with respect to the axis of the roller 10 (the roller 10 heads for the lowermost point of the groove 5a, 5b). Due to this effect and a centering action, if three or more gripping devices are used, the admissible position tolerance of a gripping system can be relatively large but guarantees at the same time a safe gripping.

FIG. 3 shows a case in which an object is from the first gripping device to the second gripping device. The substrate support is still held in the grove 5a by the gripping means 9a of the first gripping device, while the gripping means 9b of the second gripping device has already engaged with the groove 5b. After removal of the first gripping device (not shown) from the substrate support 1, the latter can be further transported by the second gripping device.

FIG. 4 shows a cross-sectional view of the wall 3 of the substrate support adapter system 1 being engaged with an alternative gripping device consisting two, three or more gripping means having a V-shaped ring groove 12; the surface 12a of said ring groove 12, which faces the outer wall, touches the convex projection 4 above and below the center plane M. The ring groove 12 is moved to the projection 4 in the direction of the arrow B. Also in this gripping device the substrate support 1 is automatically aligned or self-aligned vertically with respect to the pressing-on direction B of the ring groove 12, because the projection 4 slides into the ring groove up to the stop on both sides of the

The substrate support adapter system according to the present invention can be used for coating one or more substrates on one or both sides. In particular, the system according to the present invention can be used for coating by means of cathode sputtering, wherein the wall 3 of the substrate support might serve as an anode surface and, for this purpose, preferably consists of a suitable metal or metal alloy.

The substrate support adapter system according to the present invention can be used as a uniform and single substrate support adapter system during the entire operating cycle in a system, and it can also be used during other treatment steps required during the process, e.g., cleaning of the substrate.

1. A substrate support (1), for receiving a substrate (13) which should be treated or coated on both sides, comprising
(a) an internal space (2) for receiving at least one substrate (13),
(b) an annular wall (3) which extends vertically with respect to a center plane (m) of the substrate support (1) and limits the internal space (2) laterally,
(c) a convex projection (4) which extends on an outer circumference (3a) of the wall (3) and whose vertex lies in the center plane (M), and
(d) two circumferential concave grooves (5a, 5b) which extend symmetrical with respect to the center plane (M) and the projection (4) and serve for engaging at least one holding or gripping means:

2. The substrate support (1) according to claim 1, wherein the substrate (13) is held by at least two substrate holders (14) at an inner side of the wall (3).

3. The substrate support (1) according to claim 1, wherein the annular wall (3) has a shape of a circular cylinder.

4. The substrate support (1) according to claim 2, wherein the inner side of the annular wall (3) is conical and an outer side of the annular wall (3) has a shape of a circular cylinder.

5. A device for manipulating the substrate support (1) according to any claim 1, comprising at least two passive holding devices (6) for being positioned on a circumference of the substrate support (1), each comprising a roller (7) which is pressed by a spring (8) against the projection (4) on one side with respect to the center plane (M), as well as a stopping surface (6a) on which a surface (4a) of the projection (4) rests on an other side with respect to the center plane (M).

6. The device according to claim 5, wherein at least three holding devices (6) are provided for being positioned on the circumference of the substrate support (1).

7. The device according to claim 5, wherein the substrate support (1) is pressed in a rolling or sliding manner over the roller (7) in a direction of arrow (A) of FIG. 2 until the surface (4a) rests on the stopping surface (6a), wherein the roller (7) detachably locks the substrate support (1) in said position in a spring-loaded manner and with a defined force.

8. The device according to claim 6, wherein the substrate support (1) is centered by means of the holding device (6).

9. A device for gripping the substrate support (1) according to claim 1, comprising at least two gripping means (9a or 9b) for being positioned on the a circumference of the substrate support (1) and having one roller (10) each, which can be engaged with one of the grooves (5a, 5b).

10. The device according to claim 9, wherein at least three gripping means (9a or 9b) are provided for being positioned on the circumference or the substrate support (1).

11. The device according to claim 9, wherein a radius of the roller (10) is smaller than a radius of the groove (5a, 5b) so that the substrate support (1) is automatically aligned vertically with respect to an axis of the roller (10) when the roller (10) engages with the groove (5a, 5b).

12. A method for manipulating a substrate support (1) according to claim 1 by means of the device according to claim 9, wherein the gripping means (9a or 9b) approaches the substrate support (1) and the roller (10) engages with the groove (5a or 5b), the gripping means (9a or 9b) transports the substrate support (1) and then releases the engagement of the roller (10) with the groove (5a or 5b).

13. The method according to claim 12, wherein the substrate support (1) is gripped and, after the first gripping means (9a) or a holding device (6) are released from the substrate support (1), held by means of a second device comprising at least two gripping means (9a or 9b) for being positioned on the a circumference of the substrate support (1) and having one roller (10) each, which can be engaged with one of the grooves (5a, 5b).

14. A device for manipulating the substrate support (1) according to claim 1, comprising a plurality of gripping means for being positioned on a circumference of the substrate support (1) and each having a V-shaped annular groove (12) whose surface (12a) facing the substrate support (1) touches the projection (4) on one side and on another side with respect to the center plane, wherein the substrate support (1) is automatically aligned vertically with respect to a pressing-on direction (B) of the annular groove (12).

15. A method for manipulating a substrate support (1) by means of the device according to claim 14, herein the annular groove (12) is moved from outside towards the substrate support (1) in radial direction (arrow B) and is engaged with the projection (4), the gripping means transports the substrate support (1) and subsequently removes the surface (12a) from the projection (4) in a radial direction towards the outside.

16. The method according to claim 12, for coating the substrate on one side or both sides.

17. The method-according to claim 16 for coating by means of cathode sputtering.

18. The method according to claim 17, wherein the wall (3) of the substrate support (1) serves as an anode surface.

19. The method according to claim 16 in CVD (chemical vapor deposition) coating processes.

20. The method according to claim 12, for cleaning the substrate.
